(19) United States
(12) Patent Application Publication
(10) Pub. No.: US 2023/0081600 A1
(43) Pub. Date: Mar. 16, 2023

(54) LIGHT-EMITTING DEVICE AND METHOD FOR MANUFACTURING THE SAME

(71) Applicant: QUANZHOU SANAN SEMICONDUCTOR TECHNOLOGY CO., LTD, Fujian (CN)

(72) Inventors: Yi-Jui HUANG, Fujian (CN); Tsung-Ming LIN, Xiamen (CN); Yu-Tsai TENG, Xiamen (CN); Chung-Ying CHANG, Xiamen (CN)

(21) Appl. No.: 17/990,567

(22) Filed: Nov. 18, 2022

Related U.S. Application Data
(63) Continuation-in-part of application No. PCT/CN2021/097810, filed on Jun. 2, 2021.

(51) Int. Cl. H01L 33/00; H01L 23/544

(52) U.S. Cl. CPC H01L 33/0095; H01L 23/544; H01L 2223/5446

(57) ABSTRACT

A light-emitting device includes a substrate and a semiconductor light-emitting stack. The substrate includes an upper surface, a first side surface, and a second side surface adjacent to the first side surface. The semiconductor light-emitting stack includes a first conductivity type semiconductor layer, a light-emitting layer, and a second conductivity type semiconductor layer that are sequentially disposed on the upper surface of the substrate in such order. The first side surface includes X number of first laser inscribed marks, and the second side surface includes Y number of second laser inscribed marks, in which Y>X>0 and Y≥3. A method for manufacturing the light-emitting device is also provided herein.

### CROSS-REFERENCE TO RELATED APPLICATION

This application is a bypass continuation-in-part application of PCT International Application No. PCT/CN2021/097810 filed on Jun. 2, 2021. The entire content of the international patent application is incorporated herein by reference.

### FIELD

The disclosure relates to a semiconductor lighting device, and more particularly to a light-emitting device and a method for manufacturing the same.

### BACKGROUND

A light-emitting device (e.g. a light emitting diode (LED)) is a semiconductor device that can emit light by utilizing a recombination of carriers to release energy. The light-emitting devices have wide applications due to advantages such as low energy consumption, long service life and high energy efficiency, and they are environmental friendly.

A conventional process for manufacturing a light-emitting device usually includes (i) forming a plurality of laser inscribed marks in a sapphire substrate of a light-emitting wafer by stealth dicing, and (ii) splitting the light-emitting wafer along the laser inscribed marks, so as to form the light-emitting devices. In such process, the sapphire substrate is a wafer that has a c-plane (0001), as shown in FIG. 1. In a splitting process for a light-emitting wafer, the light-emitting wafer is required to be split into a plurality of dies. In such case, each of two dicing directions that are perpendicular to each other is perpendicular to the c-plane (0001) of the sapphire substrate of the light-emitting wafer, and the two dicing directions are generally corresponding to two planes (1120), (1010) of the sapphire substrate, respectively. Because the plane (1010) is located proximate to a slip plane (1102), and the slip plane (1102) is not perpendicular to the c-plane (0001) but has a certain oblique angle with the c-plane, a single die obtained after the laser splitting process has a lattice shift along the slip plane (1102) and the cleavage direction of the die in the plane (1010) is changed, thereby forming cracks that deviate from a central position of a dicing line in the laser splitting process. When the dicing line has a larger width, the location of the cracks can be prevented from extending to an electrode area of the light-emitting device. However, in order to increase production yield of the light-emitting device as much as possible during processing, the width of the dicing line should be restrained, so there is risk of damage to the electrode area of the light-emitting device during the laser splitting process, which may induce leakage in the light-emitting device. As shown in FIG. 2, after the light-emitting wafer is split to form the light-emitting device, an included angle formed between a side surface and a bottom surface of the light-emitting device has an angle ranging from 80° to 100°, which may facilitate formation of irregular edges (e.g., having different size or irregular shape) of a light-emitting stack of the light-emitting device. FIG. 3 illustrates a plurality of the light-emitting devices shown in FIG. 2 arranged on a support film, and it can be seen that the backsides (shown facing up in FIG. 3) of the light-emitting devices have an irregular shape, thereby causing non-uniform distribution of light when the light-emitting devices are in operation and light is emitted from the light-emitting stack of the light-emitting devices in a direction away from the support film. FIG. 4 illustrates a light distribution curve of a light-emitting device with the irregular backside shown in FIG. 2, and it shows an asymmetrical light distribution which is due to the distorted edges of the light-emitting device.

### SUMMARY

Therefore, an object of the disclosure is to provide a light-emitting device and a method for manufacturing the same that can alleviate or overcome the aforesaid shortcomings of the prior art.

According to a first aspect of the disclosure, a light-emitting device includes a substrate and a semiconductor light-emitting stack.

The substrate includes an upper surface, a first side surface, and a second side surface adjacent to the first side surface.

The semiconductor light-emitting stack includes a first conductivity type semiconductor layer, a light-emitting layer, and a second conductivity type semiconductor layer.

The first conductivity type semiconductor layer is disposed over the upper surface of the substrate.

The light-emitting layer is disposed on the first conductivity type semiconductor layer opposite to the substrate.

The second conductivity type semiconductor layer is disposed on the light-emitting layer opposite to the first conductivity type semiconductor layer.

The first side surface includes X number of first laser inscribed marks, and the second side surface includes Y number of second laser inscribed marks, in which Y>X>0 and Y≥3.

According to a second aspect of the disclosure, a method for manufacturing a light-emitting device includes the steps of:

a) providing a light-emitting wafer which includes a substrate and a plurality of semiconductor light-emitting stacks spaced apart from one another by dicing lines, the dicing lines having a first dicing line that extends in a first direction, and a second dicing line that extends in a second direction substantially perpendicular to the first direction, each of the semiconductor light-emitting stacks including a first conductivity type semiconductor layer, a light-emitting layer, and a second conductivity type semiconductor layer that are sequentially disposed on the substrate along a thickness direction that is perpendicular to the first direction and the second direction;

b) forming X number of first laser inscribed features in a cross sectional plane of the substrate along the first dicing line;

c) forming Y number of second laser inscribed features in a cross sectional plane of the substrate along the second dicing line, in which Y>X>0 and Y≥3; and

d) splitting the light-emitting wafer along the dicing lines to obtain a plurality of light-emitting devices.

### BRIEF DESCRIPTION OF THE DRAWINGS

Other features and advantages of the disclosure will become apparent in the following detailed description of the embodiment(s) with reference to the accompanying drawings, in which:

FIG. 1 is a schematic view illustrating a lattice structure of a sapphire substrate;

FIG. 2 is a picture showing a conventional light-emitting device;

FIG. 3 is a picture showing a plurality of the conventional light-emitting devices disposed on a plate;

FIG. 4 is a curve illustrating a light distribution of the conventional light-emitting device;

FIG. 5 is a flow chart illustrating consecutive steps of a method for manufacturing a first embodiment of a light-emitting device according to the disclosure;

FIGS. 6 to 11 are schematic views illustrating the consecutive steps of the method for manufacturing the first embodiment of the light-emitting device, in which FIG. 6 shows a cross-sectional side view of a semiconductor light-emitting laminate of the light-emitting device, FIG. 7 shows the light-emitting device of FIG. 6 distributed on a light-emitting wafer, and first and second dicing lines defined in the light-emitting device of FIG. 6, FIG. 8 shows first laser inscribed features formed in the substrate along the first dicing line, FIG. 9 shows second laser inscribed features formed in the substrate along the second dicing line, FIG. 10 shows a plurality of first laser inscribed marks formed on a first side surface (corresponding to the first dicing line) of the substrate after step S140, and FIG. 11 shows a plurality of second laser inscribed marks formed on a second side surface (corresponding to the second dicing line) of the substrate after step S140;

FIG. 12 is a scanning electron microscope (SEM) image showing the first laser inscribed marks formed on the first side surface of the substrate of the light-emitting device of the first embodiment;

FIG. 13 is a SEM image showing the second laser inscribed marks formed on the second side surface of the substrate of the light-emitting device of the first embodiment;

FIG. 14 is a schematic top view of the light-emitting device according to the disclosure;

FIG. 15 is a flow chart illustrating consecutive steps of a method for manufacturing a second embodiment of the light-emitting device according to the disclosure;

FIG. 16 is a SEM image showing the first laser inscribed marks formed on the first side surface of the substrate of the light-emitting device of the second embodiment;

FIG. 17 is a SEM image showing the second laser inscribed marks formed on the second side surface of the substrate of the light-emitting device of the second embodiment;

FIG. 18 is a picture showing a plurality of the light-emitting devices of the second embodiment arranged on a plate;

FIG. 19 is a graph illustrating a light intensity distribution of the light-emitting device of the second embodiment;

FIG. 20 is a schematic view illustrating a third embodiment of the light-emitting device according to the disclosure;

FIG. 21 is a schematic view illustrating a fourth embodiment of the light-emitting device according to the disclosure;

FIG. 22 is a schematic view illustrating a fifth embodiment of the light-emitting device according to the disclosure; and

FIG. 23 is a SEM image showing the first laser inscribed marks formed on the first side surface of the substrate of the light-emitting device of the fifth embodiment.

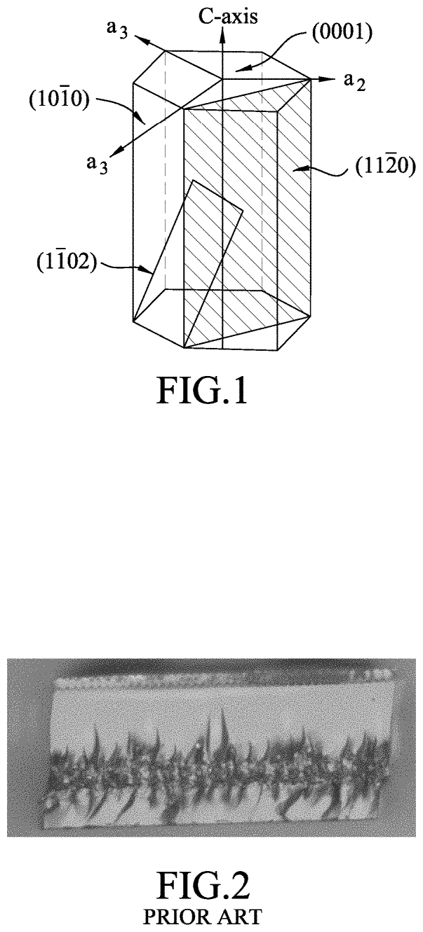

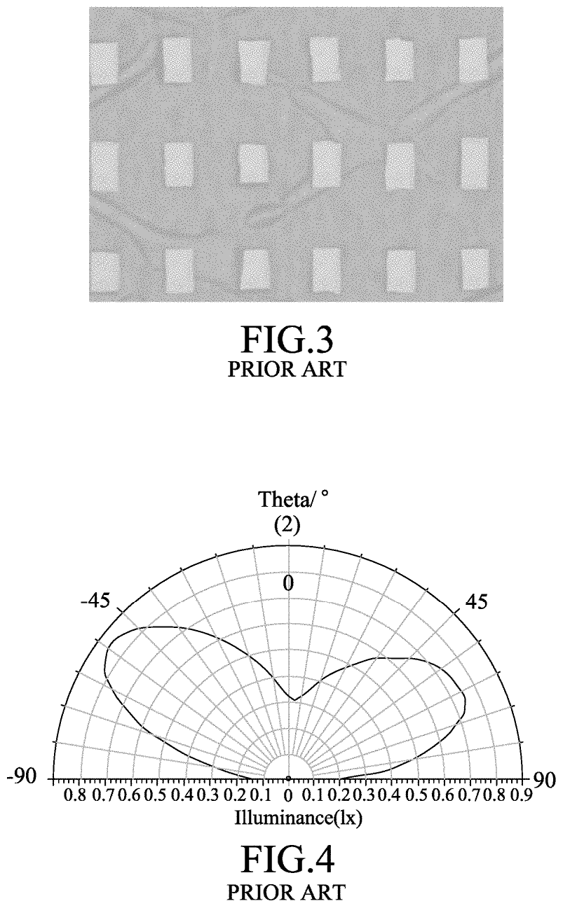

### DETAILED DESCRIPTION

Before the disclosure is described in greater detail, it should be noted that where considered appropriate, reference numerals have been repeated among the figures to indicate corresponding or analogous elements, which may optionally have similar characteristics.

It should be noted that, directional terms, such as “vertical,” “horizontal,” “top,” “bottom,” “upper,” and “lower,” may be used to assist in describing the disclosure based on the orientation of the embodiments shown in the figures. The use of these directional definitions should not be interpreted to limit the disclosure in any way.

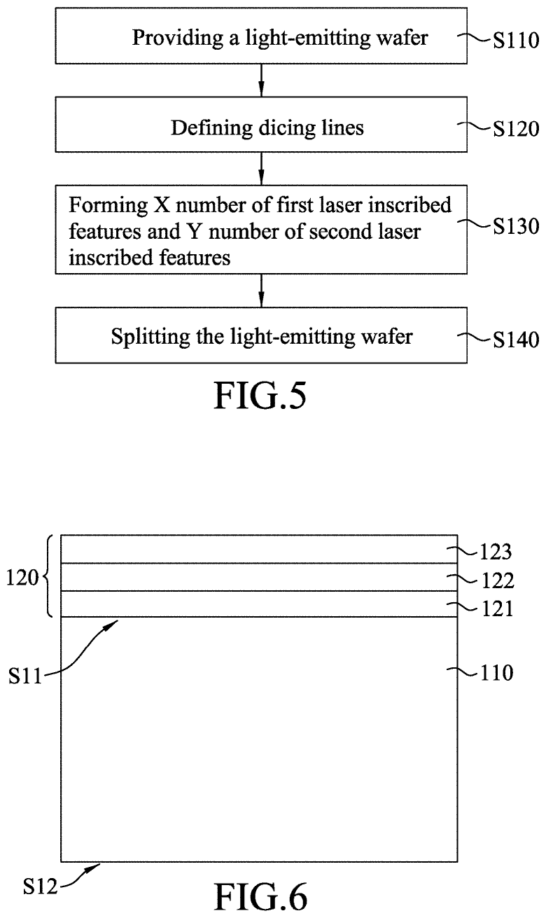

Referring to FIG. 5, this disclosure provides a method for manufacturing a first embodiment of a light-emitting device according to the present disclosure, which includes the following steps S110 to S140. FIGS. 6 to 11 illustrate intermediate stages of the method for manufacturing the first embodiment of the light-emitting device. It is noted that a laser having variable power refers to the power of the laser's laser beam is different when focused at different focal points.

In step S110, as shown in FIG. 6, a light-emitting wafer is provided. The light-emitting wafer includes a substrate 110 and a semiconductor light-emitting laminate 120. The substrate 110 may be made of a light-transmissive material or a translucent material, so that light emitted from semiconductor light-emitting stacks 120′ obtained from the semiconductor light-emitting laminate 120 can pass through the substrate 110. The substrate 110 may be used as a growth substrate for growing the semiconductor light-emitting stacks 120′, and may be a sapphire substrate, a gallium nitride (GaN) substrate, or an aluminum nitride (AlN) substrate. The substrate 110 includes an upper surface S11, a lower surface S12 opposite to the upper surface S11, and side surfaces connecting the upper surface S11 and the lower surface S12. The substrate 110 may include a plurality of protrusions that are formed on at least a part of the upper surface S11. In certain embodiments, the substrate 110 may be a patterned sapphire substrate. The semiconductor light-emitting stacks 120′ may be formed on the substrate 110 by one of physical vapor deposition (PVD), chemical vapor deposition (CVD), epitaxial growth technology, and atomic layer deposition (ALD). The substrate 110 may have a thickness ranging from 80 μm to 750 μm. The semiconductor light-emitting laminate 120 includes a first conductivity type semiconductor layer 121, a light-emitting layer 122, and a second conductivity type semiconductor layer 123 that are sequentially disposed on the substrate 110 along a thickness direction of the substrate 110. The first conductivity type semiconductor layer 121 is disposed on the upper surface S11 of the substrate 110, the light-emitting layer 122 is disposed on the first conductivity type semiconductor layer 121 opposite to the substrate 110, and the second conductivity type semiconductor layer 123 is disposed on the light-emitting layer 122 opposite to the first conductivity type semiconductor layer 121. Specifically, the semiconductor light-emitting laminate 120 may include a group III-V compound semiconductor material, such as nitrides (e.g., aluminum nitride, gallium nitride, or indium nitride), phosphides (e.g., aluminum phosphide, gallium phosphide, or indium phosphide), or arsenides (e.g., aluminum arsenide, gallium arsenide, or indium arsenide). In certain embodiments, the semiconductor light-emitting laminate 120 is made of an aluminum gallium indium phosphide (AlGaInP)-based semiconductor material, and is first grown on a growth substrate made of gallium arsenide followed by being transferred to the substrate 110. The first conductivity type semiconductor layer 121 may include one of an n-type impurity (e.g., silicon, germanium, or tin) and a p-type impurity (e.g., magnesium, strontium, or barium). The second conductivity type semiconductor layer 123 may include the other one of the n-type impurity (e.g., silicon, germanium, or tin) and the p-type impurity (e.g., magnesium, strontium, or barium). The light-emitting layer 122 may be formed with a multilayered quantum well (MQW) structure, and an elemental composition ratio of the light-emitting layer 122 may be adjusted to emit light of a desired emission wavelength.

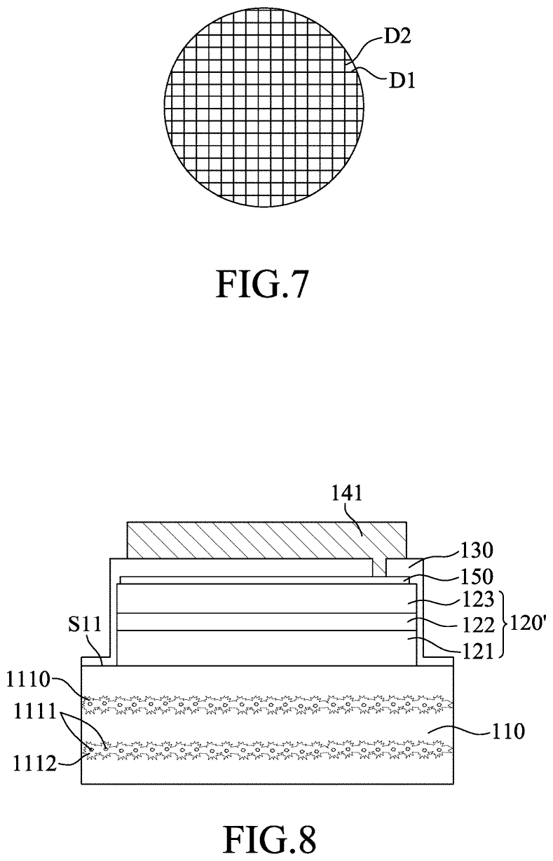

In step S120, as shown in FIG. 7, dicing lines are defined on the light-emitting wafer. The dicing lines have a first dicing line that extends in a first direction (D1), and a second dicing line that extends in a second direction (D2) substantially perpendicular to the first direction (D1). The thickness direction of the substrate 110 is substantially perpendicular to the first direction (D1) and the second direction (D2). Specifically, the substrate 110 is formed as a crystal structure, and the upper surface S11 of the substrate 110 is a c-plane. The crystal structure of the substrate 110 includes a slip plane that has an included angle relative to the c-plane, and a crystalline plane in the second direction (D2) is perpendicular to the c-plane and is located proximate to the slip plane. In certain embodiments, the substrate 110 is made of sapphire, the first dicing line is located corresponding in position to a plane of the crystal structure of the substrate 110 that is resistant to cracking (e.g., a-plane), and the second dicing line is located corresponding in position to a plane of the crystal structure of the substrate 110 that is easily cracked (e.g., m-plane). As shown in FIG. 7, in this embodiment, a plurality of the first dicing lines and a plurality of the second dicing lines are defined. In certain embodiments, the second conductivity type semiconductor layer 123, the light-emitting layer 122 and the first conductivity type semiconductor layer 121 of the semiconductor light-emitting laminate 120 are etched to form the dicing lines that expose the upper surface S11 of the substrate 110. The semiconductor light-emitting laminate 120 is thus formed into a plurality of the semiconductor light-emitting stacks 120′ that are spaced apart from one another by the dicing lines. Step S120 may be conducted by a photolithography process or multiple photolithography processes. Each of the semiconductor light-emitting stacks 120′ has a first-electrode-forming area and a second-electrode-forming area on which electrodes are to be formed (to be described below). In step S120, in the first-electrode-forming area of each of the semiconductor light-emitting stacks 120′, the second conductivity type semiconductor layer 123 and the light-emitting layer 122 are etched to expose a part of the first conductivity type semiconductor layer 121, so that one of the electrodes that is to be formed on the first-electrode-forming area is electrically connected to the first conductivity type semiconductor layer 121.

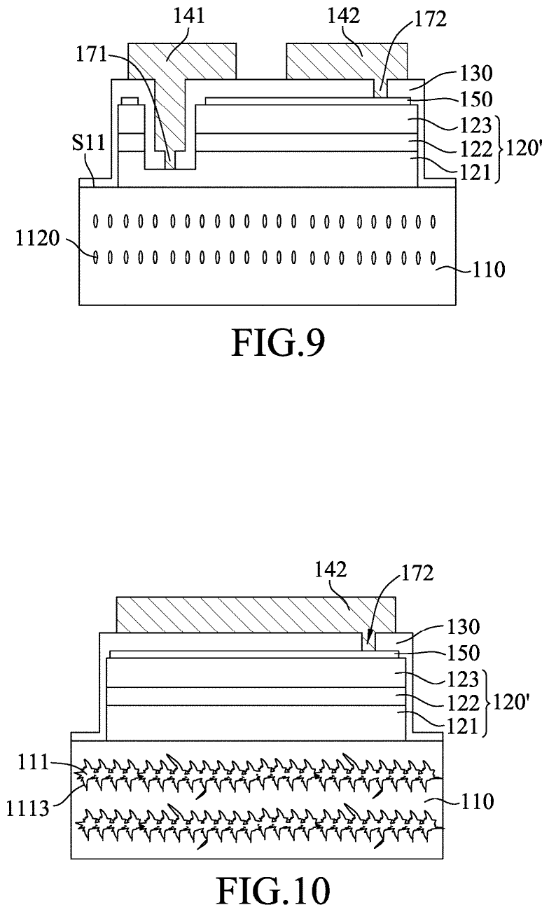

As shown in FIG. 8, in this step, an insulating layer 130 may be formed to cover upper and side surfaces of each of the semiconductor light-emitting stacks 120′, and a portion of the upper surface S11 of the substrate 110. The thickness of the insulating layer 130 on the side surfaces of each of the semiconductor light-emitting stacks 120′ is usually smaller than that of the insulating layer 130 on the upper surface of each of the semiconductor light-emitting stacks 120′ and the upper surface S11 of the substrate 110. This may be due to a shadow effect which may be caused by a well-known deposition technique, such as evaporation or sputtering. In certain embodiments, a ratio of the thickness of the insulating layer 130 on the side surfaces of each of the semiconductor light-emitting stacks 120′ to the upper surface thereof may range from 40% to 90%. In certain embodiments, before formation of the insulating layer 130, a contact electrode 150 may be formed on the upper surface of each of the semiconductor light-emitting stacks 120′, and may be made of one of indium tin oxide (ITO), gallium tin oxide (GTO), gallium zinc oxide (GZO), zinc oxide (ZnO), and combinations thereof. As shown in FIGS. 8 and 9, in this step, after the formation of the insulating layer 130, a first electrode 141 and a second electrode 142 are formed on the insulating layer 130 and respectively in the first-electrode-forming area and the second-electrode-forming area of each of the semiconductor light-emitting stacks 120′ by photolithography and evaporation processes. A minimum horizontal distance between the first electrode 141 and the second electrode 142 on the insulating layer 130 may not be smaller than 5 μm, such as ranging from 20 μm to 40 μm, ranging from 40 μm to 60 μm, ranging from 60 μm to 80 μm, or ranging from 80 μm to 120 μm. Each of the first electrode 141 and the second electrode 142 may be made of a metal, such as chromium, platinum, gold, titanium, nickel, aluminum, or combinations thereof. In certain embodiments, each of the first electrode 141 and the second electrode 142 may be formed as a multilayered structure, and the uppermost layer thereof may be made of gold. The insulating layer 130 may have a first through hole 171 and a second through hole 172. The first electrode 141 passes through the first through hole 171 to be electrically connected to the first conductivity type semiconductor layer 121, and the second electrode 142 passes through the second through hole 172 to be electrically connected to the contact electrode 150.

In step S130, a laser beam is provided and focused in the substrate 110 to form first and second laser inscribed features 1110, 1120. In this step, X number of the first laser inscribed features 1110 are formed in a cross sectional plane, which is resistant to cracking (e.g., a-plane), of the substrate 110 along each of the first dicing lines, and Y number of the second laser inscribed features 1120 are formed in a cross sectional plane, which is easily cracked (e.g., m-plane), of the substrate 110 along each of the second dicing lines, in which Y≥X≥1. Specifically, at least one first laser inscribed feature 1110 is formed in the substrate 110 using a first laser beam (two of the first laser inscribed features 1110 are shown in FIG. 8), and at least one second laser inscribed feature 1120 is formed in the substrate 110 using a second laser beam (two of the second laser inscribed features 1120 are shown in FIG. 9). In this embodiment, a pulse energy of the first laser beam is greater than that of the second laser beam. The first dicing lines are located corresponding in position to the plane of the substrate 110 that is resistant to cracking, so that the at least one first laser inscribed feature 1110 is continuously formed in the substrate 110 along the first dicing line using the first laser beam. In certain embodiments, the first laser inscribed feature 1110 or an uppermost one of the first laser inscribed features 1110 (when X is greater than 1) in the substrate 110 has a minimum distance from an upper surface S11 of the substrate 110 that is not smaller than 15 μm, such as ranging from 20 μm to 60 μm, so as to ensure that the semiconductor light-emitting stacks 120′ would not be damaged by the laser beam when the laser beam is focused inside the substrate 110. In certain embodiments, when X is greater than 1, a distance between two adjacent first laser inscribed features 1110 may range from 10 μm to 50 μm. The at least one first laser inscribed feature 1110 includes a plurality of first explosion points 1111 that are spaced apart from each other, and first extending portions 1112 that extends outwardly and irregularly from the first explosion points 1111, respectively. In certain embodiments, a distance between two adjacent ones of the first explosion points 1111 may range from 1 μm to 12 μm, such as from 3 μm to 5 μm, from 5 μm to 8 μm, or from 8 μm to 12 μm. When the distance between two adjacent ones of the first explosion points 1111 is smaller than 1 μm, a formation efficiency for the first explosion points 1111 may be adversely affected. When the distance between two adjacent ones of the first explosion points 1111 is greater than 12 μm, the at least one first laser inscribed feature 1110 may not be formed continuously, so that the light-emitting wafer is difficult to split. In this embodiment, the distance between two adjacent ones of the first explosion points 1111 ranges from 3 μm to 7 μm. The second dicing line is located corresponding in position to the plane of the substrate 111 that is easily cracked, so that the at least one second laser inscribed feature 1120 is discontinuously formed in the substrate 110 along the second dicing line using the second laser beam. In certain embodiments, the second laser inscribed feature 1120 or an uppermost one of the second laser inscribed features 1120 (when Y is greater than 1) in the substrate 110 has a minimum distance from an upper surface S11 of the substrate 110 that is not smaller than 10 μm, such as ranging from 15 μm to 50 μm. When the aforesaid minimum distance between the second laser inscribed feature 1120 and the upper surface S11 of the substrate 110 is too small (e.g., small than 10 μm), the semiconductor light-emitting stacks 120′ may be damaged by the laser beam when the laser beam is focused inside the substrate 110, and during the process of splitting the light-emitting wafer, cracks may be formed and extend to the semiconductor light-emitting stacks 120′, the insulating layer 130, the first electrode 141, or the second electrode 142. When the aforesaid minimum distance between the second laser inscribed feature 1120 and the upper surface S11 of the substrate 110 is too large (e.g., larger than 50 μm), the cracks may be formed along the plane (11̅02) during the process of splitting the light-emitting wafer. When Y is greater than 1, the second laser inscribed features 1120 in the substrate 110 are regularly arranged. In certain embodiments, the second laser inscribed feature 1120 may include a plurality of second explosion points (not shown) that are spaced apart from each other, and second extending portions (not shown) that extends outwardly from the second explosion points, respectively. In certain embodiments, a distance between two adjacent ones of the second explosion points may range from 5 μm to 20 μm, such as from 8 μm to 12 μm. In certain embodiments, a distance between two adjacent ones of the first explosion points 1111 is smaller than that between two adjacent ones of the second explosion points. In such case, the distance between two adjacent ones of the first explosion points 1111 may range from 1 μm to 12 μm, and the distance between two adjacent ones of the second explosion points may range from 5 μm to 20 μm.

In this embodiment, formation of X number of the first laser inscribed features 1110 or Y number of the second laser inscribed features 1120 involve using one beam laser focusing at multiple focal points. The first laser beam for forming X number of the first laser inscribed features 1110 may have an average power ranging from 0.07 milliwatts (mW) to 5 mW, and the second laser beam for forming Y number of the second laser inscribed features 1120 may have an average power ranging from 0.03 mW to 3 mW. In certain embodiments, the focal points of the second laser beam in the substrate 110 may have a minimum distance from the upper surface S11 of the substrate 110 not smaller than 10 μm.

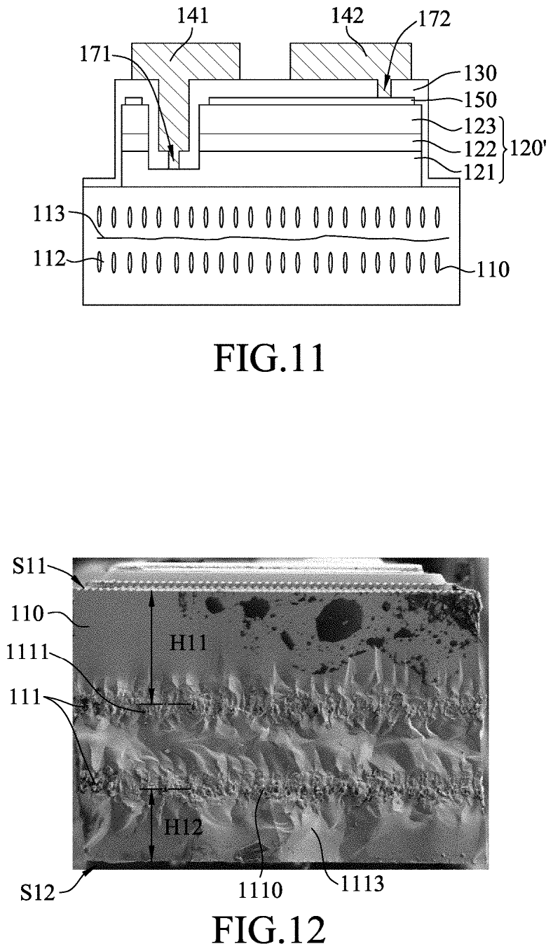

In step S140, as shown in FIGS. 10 and 11, the light-emitting wafer is split along the first and second dicing lines to obtain a plurality of light-emitting devices. The substrate 110 of each of the light-emitting devices includes a first side surface and a second side surface adjacent to the first side surface, and the first side surface (corresponding to the first dicing line) includes X number of the first laser inscribed marks 111. In this embodiment, the first side surface includes two of the first laser inscribed marks 111 that are arranged in parallel in the thickness direction. Each of the first laser inscribed marks 111 includes a corresponding one of the first inscribed features 1110 (see FIG. 8) and a plurality of cracks 1113 extending up and down from the corresponding one of the first inscribed features 1110. The second side surface (corresponding to the second dicing line) includes Y number of the second laser inscribed marks 112 and a transverse crack 113. The first laser inscribed marks 111 are rougher than the second laser inscribed marks 112. That is, the second laser inscribed marks 112 have relatively regular and fine texture compared to the first laser inscribed marks 111. The second laser inscribed marks 112 may be regularly arranged. In certain embodiments, the second laser inscribed marks 112 may be arranged in parallel in the thickness direction, and a distance between two adjacent ones of the second laser inscribed marks 112 is greater than 0 μm and is not greater than 30 μm.

FIG. 12 is an SEM image showing the first side surface of the light-emitting device, in which two of the first laser inscribed marks 111 that are arranged in parallel are observed. One of the first laser inscribed marks 111 is located proximate to the upper surface S11 of the substrate 110, and a distance (H11) between the first explosion points 1111 of the one of the first laser inscribed marks 111 and the upper surface S11 of the substrate 110 ranges from 30 μm to 60 μm, such as 40 μm. The other one of the first laser inscribed marks 111 is located proximate to the lower surface S12 of the substrate 110, and a distance (H12) between the first explosion points 1111 of the other one of the first laser inscribed marks 111 and the lower surface S12 ranges from 20 μm to 50 μm, such as 30 μm or 50 μm. In this embodiment, by controlling the distance (H11) between the first explosion points 1111 of the one of the first laser inscribed marks 111 and the upper surface S11 of the substrate 110, the crack 1113 might be prevented from extending to the upper surface S11 of the substrate 110.

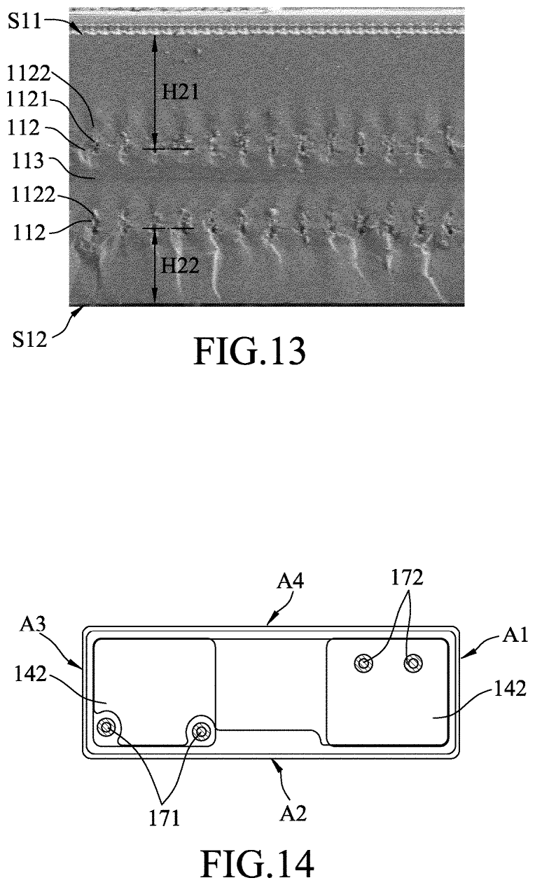

FIG. 13 is an SEM image showing the second side surface of the light-emitting device, in which two of the second laser inscribed marks 112 that are arranged in parallel are observed. Each of the second laser inscribed marks 112 includes the second explosion points 1121 located at a central line thereof, and second extending portions 1122 extending outwardly from the second explosion points 1121, respectively. The second extending portions 1122 of one of the second laser inscribed marks 112 and the second extending portions 1122 of the other one of the second laser inscribed marks 112 are separated from each other. In certain embodiments, the second extending portions 1122 of the one of the second laser inscribed marks 112 are connected to the second extending portions 1122 of the other one of the second laser inscribed marks 112. The one of the second laser inscribed marks 112 is located proximate to the upper surface S11 of the substrate 110, and a distance (H21) between the second explosion points 1121 of the one of the second laser inscribed marks 112 and the upper surface S11 of the substrate 110 ranges from 20 μm to 60 μm. The other one of the second laser inscribed marks 112 is located proximate to the lower surface S12 of the substrate 110, and a distance (H22) between the second explosion points 1121 of the other one of the second laser inscribed marks 112 and the lower surface S12 of the substrate 110 ranges from 10 μm to 60 μm, such as from 30 μm to 50 μm. The second extending portions 1122 of the one of the second laser inscribed marks 112 do not extend to the upper surface S11 of the substrate 110, and have a size that is smaller than that of the second extending portions 1122 of the other one of the second laser inscribed marks 112. The second extending portions 1122 of the other one of the second laser inscribed marks 112 extend toward the lower surface S12 of the substrate 110, and some of the second extending portions 1122 are located proximate to or may reach the lower surface S12 of the substrate 110. The transverse crack 113 is located between the two of the second laser inscribed marks 112, and the second extending portions 1122 of each of the second laser inscribed marks 112 extend along the thickness direction of the substrate 110 and terminate at the transverse crack 113. For example, the second extending portions 1122 of the one of the second laser inscribed marks 112 that is located proximate to the upper surface S11 of the substrate 110 extend toward the lower surface S12 of the substrate 110 and terminate at the transverse crack 113. In certain embodiments, the transverse crack 113 may be parallel to the upper surface S11 of the substrate 110.

In this embodiment, the first laser beam having the relatively large pulse energy is used to form the first laser inscribed features 1110 each with a relatively large damage on the plane that is resistant to cracking, which is conducive for effectively splitting the light-emitting wafer to obtain the light-emitting devices, and avoiding undesired connection of the light-emitting devices. The second laser beam having the relatively small pulse energy is used to form the second laser inscribed features 1120 each with a relatively small damage on the plane that is easily cracked, which is conducive for preventing the cracks from being formed along the slip plane during the splitting process, and preventing the cracks from reaching and damaging the semiconductor light-emitting stacks 120′ disposed on the upper surface S11 of the substrate 110 or the first and second electrodes 141, 142 during the subsequent splitting process, thereby avoiding malfunction of the light-emitting devices.

In certain embodiments, as shown in FIG. 14, the light-emitting device of this disclosure may be a flip-chip light-emitting device having a rectangular shape or a square shape. The substrate 110 of the light-emitting device has a first side A1, a second side A2, a third side A3, and a fourth side A4 that are arranged in such order in a clockwise direction. The first side A1 and the third side A3 are arranged in parallel, the second side A2 and the fourth side A4 are arranged in parallel, and the first side A1 and the third side A3 have a length shorter than that of the second side A2 and the fourth side A4. In certain embodiments, the light-emitting device may have a smaller horizontal cross sectional area and a smaller size. For example, the horizontal cross sectional area of the light-emitting device may be not larger than 62500 μm², such as ranging from 900 μm² to 62500 μm². The horizontal cross sectional area of the light-emitting device may correspond to the size of the upper surface S11 of the substrate 110. For example, the upper surface S11 of the substrate 110 may have a length that is not greater than 300 μm, such as from 200 μm to 300 μm, from 100 μm to 200 μm, or from 30 μm to 150 μm. For another example, the upper surface S11 of the substrate 110 may have a length that is not greater than 100 μm. In certain embodiments, the upper surface S11 of the substrate 110 has a regular shape (e.g., rectangular shape). The substrate 110 may have a thickness ranging from 30 μm to 160 μm, such as from 50 μm to 80 μm, from 80 μm to 120 μm, or from 120 μm to 160 μm. The semiconductor light-emitting stack 120′ may have a thickness ranging from 4 μm to 10 μm. By having the abovementioned size, length and thickness, the light-emitting device might be easily applied to small-sized and/or thin light-emitting devices or electronic devices.

Referring back to FIG. 12, the first side A1 or the third side A3 is connected to the first side surface. Referring back to FIG. 13, the second side A2 or the fourth side A4 is connected to the second side surface. In this embodiment, the plane of the substrate 110 that is resistant to cracking is to be formed into the first side surface (e.g., the first side A1 or the third side A3), and the plane of the substrate 110 that is easily cracked is to be formed into the second side surface (e.g., the second side A2 or the fourth side A4).

In certain embodiments, the insulating layer 130 is referred to as a first reflection layer, which is insulating and is disposed on and covers the upper and side surfaces of each of the semiconductor light-emitting stacks 120′. When light emitted from the light-emitting layer 122 passes through the contact electrode 150 and transmits to the surface of the insulating layer 130, most of the light would be reflected back to the semiconductor light-emitting stack 120′ by the insulating layer 130, and would pass through the lower surface S12 of the substrate 110, and thereby reduce light loss caused by the light transmitting through the upper and side surfaces of the semiconductor light-emitting stack 120′. In certain embodiments, at least 80% (or at least 90%) of the light emitted from the light-emitting layer 122 and transmitted to the surface of the insulating layer 130 would be reflected by the insulating layer 130. The insulating layer 130 may include a distributed Bragg reflector (DBR) layer. The DBR layer may include multiple laminated units which contain at least two insulating layers that have different refractive indices. The at least two layers are alternately stacked in the DBR layer to form the multiple laminated units. The number of the laminated units may range from 4 to 20. The insulating layer 130 may include titanium dioxide (TiO₂), silicon dioxide (SiO₂), hafnium dioxide (HfO₂), zirconium dioxide (ZrO₂), niobium pentoxide (Nb₂O₅), or magnesium fluoride (MgF₂). In certain embodiments, the laminated units may be composed of a titanium dioxide layer and a silicon dioxide layer. Each of the layers in the DBR layer may have an optical thickness that is equal to a quarter of an emission wavelength of the light emitted from the light-emitting layer 122. In certain embodiments, the insulating layer 130 may include a topmost layer that is made of silicon nitride (SiNx) and that may have excellent moisture-proof properties, which can prevent the light-emitting device from being affected by moisture. When the insulating layer 130 includes the DBR layer, the insulating layer 130 may further include a bottom layer or an interfacial layer that can increase the completeness of the coverage of the DBR layer on the semiconductor light-emitting stack 120′. For example, the insulating layer 130 may include an interfacial layer that is made of silicon dioxide and that has a thickness ranging from 0.2 μm to 1.0 μm, and the DBR layer contains the silicon dioxide layers and the titanium dioxide layers which are alternately stacked on the interfacial layer.

In certain embodiments, the insulating layer 130 may be a single layer, and may have a reflectance that is lower than that of the DBR layer. In such case, at least 40% of the light emitted from the light-emitting layer 122 may pass through the insulating layer 130. The insulating layer 130 may have a thickness that is not smaller than 1 μm, e.g., not smaller than 2 μm. The insulating layer 130 may be made of silicon dioxide and may have excellent moisture-proof properties, which can prevent the light-emitting device from being affected by moisture.

The contact electrode 150 may form an ohmic contact with the second conductivity type semiconductor layer 123. The contact electrode 150 may include a transparent conducting layer. The transparent conducting layer may be made of a transparent conducting oxide or a transparent metal layer. The transparent conducting oxide may further include various dopants. Examples of the transparent conducting oxide include indium tin oxide (ITO), zinc oxide, indium tin zinc oxide, indium zinc oxide, zinc tin oxide, gallium indium tin oxide, gallium indium oxide, gallium zinc oxide, zinc oxide doped with aluminum, and tin oxide doped with fluoride. Examples of the transparent metal layer include nickel, gold, and combinations thereof. The contact electrode 150 may have a thickness ranging from 20 nm to 300 nm. A surface contact resistance between the contact electrode 150 and the second conductivity type semiconductor layer 123 may be lower than that between the second conductivity type semiconductor layer 123 and a metal electrode disposed on the second conductivity type semiconductor layer 123 (when the contact electrode 150 is not disposed between the metal electrode and the second conductivity type semiconductor layer 123), which may lower a forward voltage of the light-emitting device and enhance luminous efficiency thereof.

Each of the first electrode 141 and the second electrode 142 is formed as a multilayered structure. Each of the first electrode 141 and the second electrode 142 may have a bottom layer that is made of a metal, such as chromium, aluminum, titanium, nickel, platinum, gold, and combinations thereof. The bottom layer may have a plurality of sublayers which may be made of one of the metals or a combination of the metals mentioned above. In certain embodiments, a topmost layer of each of the first electrode 141 and the second electrode 142 may be made of tin. In alternative embodiments, the topmost layer of each of the first electrode 141 and the second electrode 142 may be made of gold.

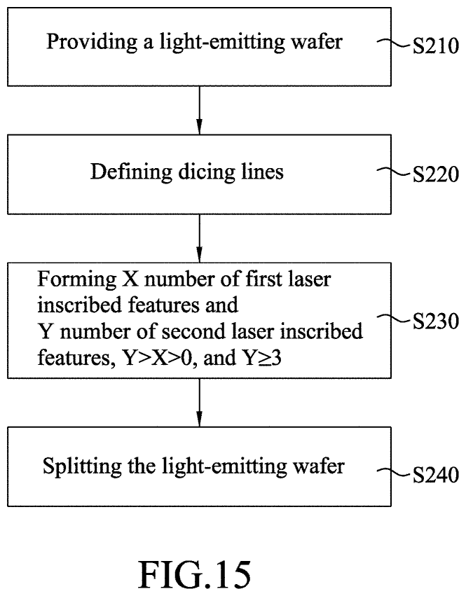

Referring to FIG. 15, this disclosure provides a method for manufacturing a second embodiment of the light-emitting device according to the present disclosure, which includes the following consecutive steps S210 to S240. The steps S210 to S240 are generally similar to the steps S110 to S140, except that in step S230, Y>X>0, and Y≥3.

In this embodiment, in step S230, the second laser beam is provided and focused at multiple focal points on a dicing plane (101̅0) that is located proximate to the slip plane (11̅02). A number of the multiple focal points ranges from 3 to 20. By utilizing the second laser beam that is focused at multiple focal points on the dicing plane (101̅0), cracks might be formed on the dicing plane (101̅0) during a subsequent splitting process (i.e., step S240), so that an included angle between the upper surface S11 of the substrate 110 and each of the first and second side surfaces of the substrate 110 might range from 85° to 95°.

Specifically, in step S230, X may range from 1 to 10, such as from 2 to 5. It is noted that when X is equal to 1 (i.e., a single focal point), the first laser beam is required to be emitted at a higher pulse energy, and the formation of the first laser inscribed mark 111 may be difficult to control, so that two adjacent light-emitting devices might not be separated, or the semiconductor light-emitting stack 120, the insulating layer 130, or the first and second electrodes 141, 142 might be damaged by the cracks that extend to the upper surface S11 of the substrate 110 during the subsequent splitting process, resulting in the malfunction of the light-emitting device.

A minimum distance between a central line (i.e., a position of a focal point) of the first laser inscribed mark 111 (when X is 1) and the upper surface S11 of the substrate 110 or the topmost one of the first laser inscribed marks 111 (when X is greater than 1) is not smaller than 10 μm, such as not smaller than 15 μm, 20 μm, 30 μm, 35 μm, or 50 μm. When the aforesaid minimum distance is smaller than 10 μm, the first extending portions 1112 formed in step S230 and the cracks formed during the subsequent splitting process (i.e., step S240) may easily extend to the upper surface S11 of the substrate 110, thereby damaging the semiconductor light-emitting stack 120′, the insulating layer 130 or the first and second electrodes 141, 142, and causing the malfunction of the light-emitting device. Y may range from 3 to 20, such as from 5 to 16, so as to achieve a substantially vertical splitting effect. A minimum distance between a central line (i.e., a position of a focal point) of the topmost one of the second laser inscribed marks 112 and the upper surface S11 of the substrate 110 is not smaller than 5 μm, such as, not smaller than 15 μm, e.g., 16 μm, 20 μm, 30 μm, or 35 μm. When the minimum distance between the central line of the topmost one of the second laser inscribed marks 112 and the upper surface S11 of the substrate 110 is smaller than 5 μm, the second extending portions 1122 and the cracks formed during the subsequent splitting process may easily extend to the upper surface S11 of the substrate 110, thereby damaging the semiconductor light-emitting stack 120′, the insulating layer 130 or the first and second electrodes 141, 142, and causing the malfunction of the light-emitting device. When the minimum distance between the central line of the topmost one of the second laser inscribed marks 112 and the upper surface S11 of the substrate 110 is greater than 50 μm, the cracks are easily formed along the plane (11̅02) during the subsequent splitting process. In certain embodiments, the second laser inscribed features 1120 may be formed using one beam laser focusing at multiple focal points, so as to avoid formation of double patterned cleavage and enhance the splitting efficiency.

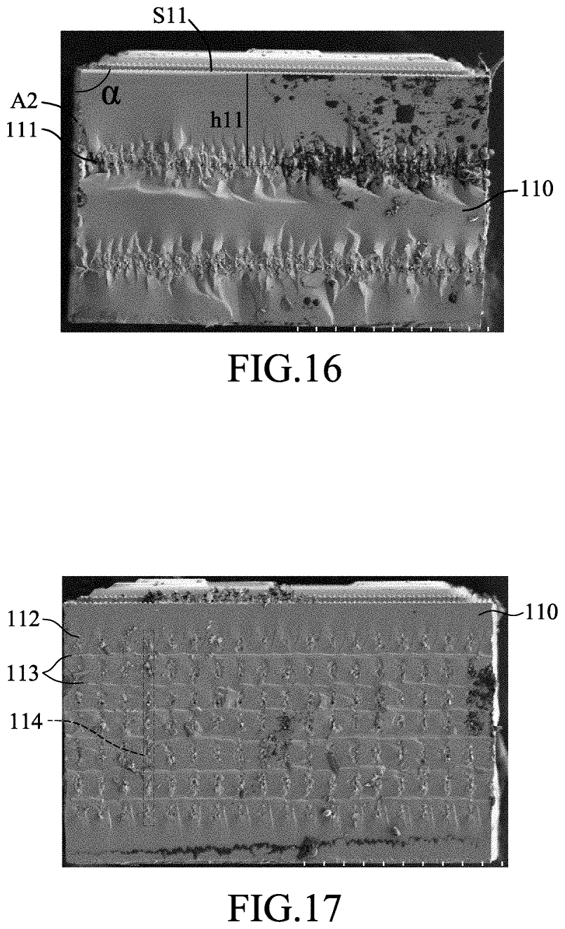

In certain embodiments, the thickness of the substrate 110 may range from 120 μm to 150 μm, the number of the first laser inscribed marks 111 that are formed on the first side surface of the substrate 110 is 2, the minimum distance between the central line of the topmost one of the first laser inscribed marks 111 that is located proximate to the upper surface S11 of the substrate 110 and the upper surface S11 of the substrate 110 ranges from 35 μm to 50 μm, the number of the second laser inscribed marks 112 that are formed on the second side surface of the substrate 110 ranges from 7 to 9, and the minimum distance between the central line of the topmost one of the second laser inscribed marks 112 that is located proximate to the upper surface S11 of the substrate 110 and the upper surface S11 of the substrate 110 ranges from 20 μm to 35 μm. FIG. 16 shows two of the first laser inscribed marks 111 that are formed on the first side surface of the substrate, and FIG. 17 shows seven of the second laser inscribed marks 112 and six transverse cracks 113 that are formed on the second side surface of the substrate 110. It can be seen that the first laser inscribed mark 111 shown in FIG. 16 is rougher and bigger than the second laser inscribed mark 112 shown in FIG. 17. In other words, the first laser inscribed mark 111 has a size wider than that of the second laser inscribed mark 112 in the thickness direction of the substrate 110, and has a depth, measured inwardly (i.e., in a direction perpendicular to the thickness direction) from the first side surface, greater than that of the second laser inscribed mark 112. Each of the first laser inscribed marks 111 has an irregularly serrated shape. Each of the second laser inscribed marks 112 is formed with a plurality of spaced-apart damaged portions, and the second laser inscribed marks 112 are spaced apart from one another by the transverse cracks 113.

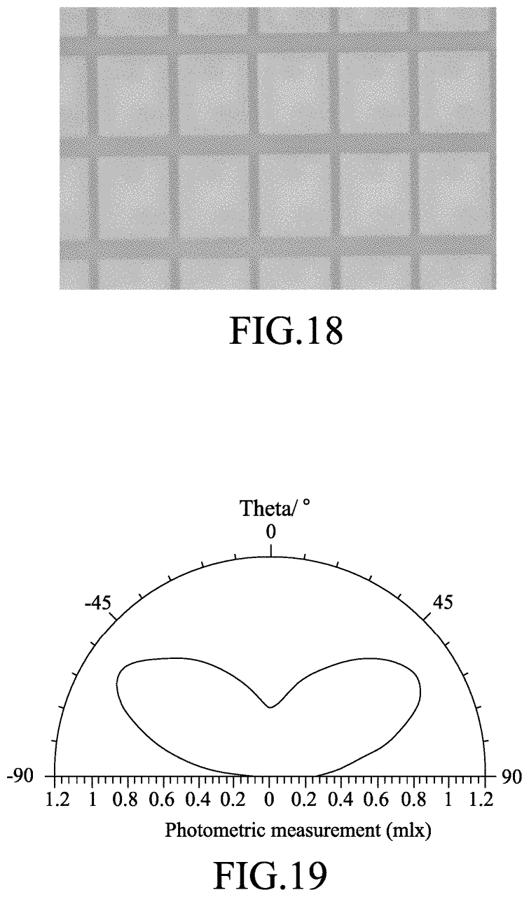

The second side surface of the substrate 110 is substantially perpendicular to the upper surface S11 of the substrate 110, and an included angle (a) between the upper surface S11 and the second side surface ranges from 85° to 95° (see FIG. 16). FIG. 18 shows the light-emitting devices arranged on a support film, and each of the light-emitting devices has a substantially square shape and no obvious distortion is found at edges of each of the light-emitting devices. In addition, the second side surface of the substrate 110 includes an upper portion, a lower portion, and a middle portion disposed between the upper portion and the lower portion, in which the upper portion and the lower portion are flat and the middle portion is rough. The second laser inscribed marks 112 and the transverse cracks 113 are located at the middle portion of the second side surface. The second laser inscribed marks 112 and the transverse cracks 113 cooperatively form almost continuous inscribed marks 114 in the thickness direction of the substrate 110. In certain embodiments, explosion points for forming the almost continuous inscribed marks 114 are in line with each other. A percentage of an area of the middle portion may be not smaller than 60% (e.g., ranging from 60% to 80%), based on a total area of the second side surface of the substrate 110, which is conducive for reducing current leakage risk of the light-emitting device. Current leakage may occur due to damage to each layer of the light-emitting device caused by laser beams or the splitting process. Moreover, due to the light-transmissive property and the relatively thick substrate 110, an amount of light emitted from the light-emitting layer 122 and passing through a side of the substrate 110 may be increased, thereby enhancing the luminous efficiency of the light-emitting device. FIG. 19 illustrates a light intensity distribution of the light-emitting device shown in FIG. 18, and exhibits a substantially symmetrical shape.

In this disclosure, the first laser beam having a relatively higher pulse energy is used to form the first laser inscribed features 1110 on the plane that is resistant to cracking and thus form the first laser inscribed marks 111 (e.g., the number thereof ranging from 2 to 5) on the first side surface (corresponding to the plane that is resistant to cracking) of the substrate 110, thereby effectively splitting the light-emitting wafer to obtain the light-emitting devices, and avoding undesired connection of the light-emitting devices. Moreover, the second laser beam having a relatively small pulse energy is used to form the second laser inscribed features 1120 on the plane that is easily cracked (e.g., m-plane) and thus form the second laser inscribed marks 112 (e.g., the number thereof ranging from 5 to 20) on the second side surface (corresponding to the plane that is easily cracked) of the substrate 110. The second laser inscribed marks 112 cooperate with the transverse cracks 113 to form the almost continuous inscribed marks 114 in the thickness direction of the substrate 110. With such second laser inscribed features 1120, splitting along the slip plane (e.g., (11̅02)) during the splitting process can be avoided to thereby obtain a vertical sidewall of the substrate 110. Furthermore, the aforesaid designs on laser energy and numbers of the first and second laser inscribed features 1110, 1120 may prevent cracks from extending to the semiconductor light-emitting stacks 120′ to further damage the semiconductor light-emitting stacks 120′ and the first and second electrodes 141, 142 and cause the malfunction of the light-emitting device.

The disclosure will be further described by way of the following examples. However, it should be understood that the following examples are solely intended for the purpose of illustration and should not be construed as limiting the disclosure in practice.

### Optical Measurement

To determine light output performance (LOP) of the light-emitting device according to this disclosure, 10 of the light-emitting devices (i.e., serving as samples in Example) of this disclosure were prepared. In each of the samples in the Example, the first side surface of the substrate has two laser inscribed marks that are formed using a laser beam focusing at two focal points, and the second side surface of the substrate has seven laser inscribed marks that are formed using a laser beam focusing at multiple focal points. The structures of the first and second side surfaces of the samples in the Example are similar to the structures shown in FIGS. 16 and 17, respectively. For comparison purposes, another 10 of light-emitting devices (i.e., serving as samples in Comparative Example) were also prepared. The structure of each of first and second side surfaces of the substrate of each of the samples in the Comparative Example is similar to that shown in FIG. 2. Each of the samples of the Example and the Comparative Example has the same structure except for the number of the laser inscribed marks formed on the first side surface and the second side surface, and was made using a similar method except for the way in which the laser inscribed marks are formed on the first side surface and the second side surface. Specifically, in step S230, a laser beam focusing at a single focal point is performed in the substrate of each of the samples in the Comparative Example along the first and second dicing lines, so as to form a single laser inscribed mark on each of the first side surface of the substrate and the second side surface of the substrate.

The samples in the Example and the Comparative Example were subjected to an optical measurement for determining the LOP thereof. The results are shown in Table 1. As shown in Table 1, the LOP of the samples in the Example was 3% higher than that of the samples in the Comparative Example.

TABLE 1

| | | Input | Input | Light output | Average | |
|---|---|---|---|---|---|---|
| | | current | volatge | performance | LOP | LOP |
| Sample | | (mA) | (V) | (LOP) (mW) | (mW) | (%) |
| Samples of the | 1 | 1.0 | 2.643 | 0.966 | 0.965 | 100.0% |
| Comparative Example | 2 | 1.0 | 2.642 | 0.961 | | |
| | 3 | 1.0 | 2.643 | 0.995 | | |
| | 4 | 1.0 | 2.642 | 0.951 | | |
| | 5 | 1.0 | 2.641 | 0.948 | | |
| | 6 | 1.0 | 2.642 | 0.957 | | |
| | 7 | 1.0 | 2.641 | 0.974 | | |
| | 8 | 1.0 | 2.641 | 0.977 | | |
| | 9 | 1.0 | 2.641 | 0.972 | | |
| | 10 | 1.0 | 2.642 | 0.951 | | |
| Samples of | 1 | 1.0 | 2.644 | 0.996 | 0.994 | 103.0% |
| the Example | 2 | 1.0 | 2.643 | 0.999 | | |
| | 3 | 1.0 | 2.644 | 1.001 | | |
| | 4 | 1.0 | 2.643 | 1.001 | | |
| | 5 | 1.0 | 2.645 | 0.998 | | |
| | 6 | 1.0 | 2.644 | 0.997 | | |
| | 7 | 1.0 | 2.645 | 0.991 | | |
| | 8 | 1.0 | 2.646 | 0.987 | | |
| | 9 | 1.0 | 2.645 | 0.988 | | |
| | 10 | 1.0 | 2.644 | 0.980 | | |

### Leakage Current Test

To determine a leakage current of the light-emitting device according to this disclosure, samples for Examples A, B, and C were prepared. In Example A, two light-emitting wafers (samples A1 and A2) were provided, and each of the light-emitting wafers has a plurality of the light-emitting devices (LEDs). In Example B, four light-emitting wafers (samples B1, B2, B3, and B4) were provided, and each of the light-emitting wafers has a plurality of the light-emitting devices (LEDs). In Example C, four light-emitting wafers (samples C1, C2, C3 and C4) were provided, and each of the light-emitting wafers has a plurality of the light-emitting devices (LEDs). The methods for manufacturing the light-emitting devices of the light-emitting wafers in Examples A, B, and C were similar, except for the number of the focal points of the laser beam. Specifically, a laser beam is focusing at a single focal point in the substrate of each of the light-emitting devices (LEDs) of the samples A1 and A2 in Example A along the first dicing line and the second dicing line; for each of the light-emitting devices (LEDs) of the samples B1, B2, B3, and B4 in Example B, a laser beam is focusing at nine focal points in the substrate along the second dicing line and another laser beam is focusing at two focal points in the substrate along the first dicing line; and a laser beam focusing at nine focal points in the substrate of each of the light-emitting devices (LEDs) of the samples C1, C2, C3, and C4 in Example C along the second dicing line and the first dicing line.

The light-emitting devices (LEDs) of the samples in Examples A, B, and C were subjected to a leakage current test. When a leakage current (IR) value of a tested light-emitting device (LED) is greater than 0.1 μA, the tested LED was determined to have leakage current (IR). The results are shown in Table 2. As shown in Table 2, the number of the LED in Example A that have the leakage current is more than that of the LED in Example B, and is also more than that of the LED in Example C. This is because during the splitting step, cracks forming in the substrate of each of the LEDs of the samples in Example A are difficult to control, and may easily damage each layer of the LED in Example A. The number of the LED in Example C that has the leakage current is more than that of the LED in Example B that has the leakage current.

TABLE 2

| | | Number of focal points | | Number of focal points | | | | | | | | | | | | |
|---|---|---|---|---|---|---|---|---|---|---|---|---|---|---|---|---|
| | | on a plane that is | | on a plane that is | | | | | | | | | | | | |
| | Sample | easily cracked | | resistant to cracking | | | Leakage current (IR) (μA) | | | | | | | | | |
| | No. | 1 | 9 | 1 | 2 | 9 | <0.05 | | 0.05~0.1 | | 0.1~1 | | 1~10 | | >10 | |
| Samples of | A1 | V | | V | | | 146425 | LEDs | 22 | LEDs | 49 | LEDs | 86 | LEDs | 127 | LEDs |
| Example A | A2 | | | | | | 34646 | LEDs | 16 | LEDs | 66 | LEDs | 71 | LEDs | 179 | LEDs |
| Samples of | B1 | | V | | V | | 141095 | LEDs | 0 | LED | 0 | LED | 0 | LED | 1 | LED |
| Example B | B2 | | | | | | 137718 | LEDs | 1 | LED | 1 | LED | 1 | LED | 5 | LEDs |
| | B3 | | | | | | 148449 | LEDs | 3 | LEDs | 0 | LED | 3 | LEDs | 1 | LED |
| | B4 | | | | | | 147508 | LEDs | 1 | LED | 3 | LEDs | 1 | LED | 0 | LED |
| Samples of | C1 | | V | | | V | 148522 | LEDs | 10 | LEDs | 4 | LEDs | 11 | LEDs | 9 | LEDs |
| Example C | C2 | | | | | | 146592 | LEDs | 15 | LEDs | 12 | LEDs | 18 | LEDs | 19 | LEDs |
| | C3 | | | | | | 148676 | LEDs | 9 | LEDs | 9 | LEDs | 16 | LEDs | 10 | LEDs |
| | C4 | | | | | | 146915 | LEDs | 9 | LEDs | 9 | LEDs | 11 | LEDs | 15 | LEDs |

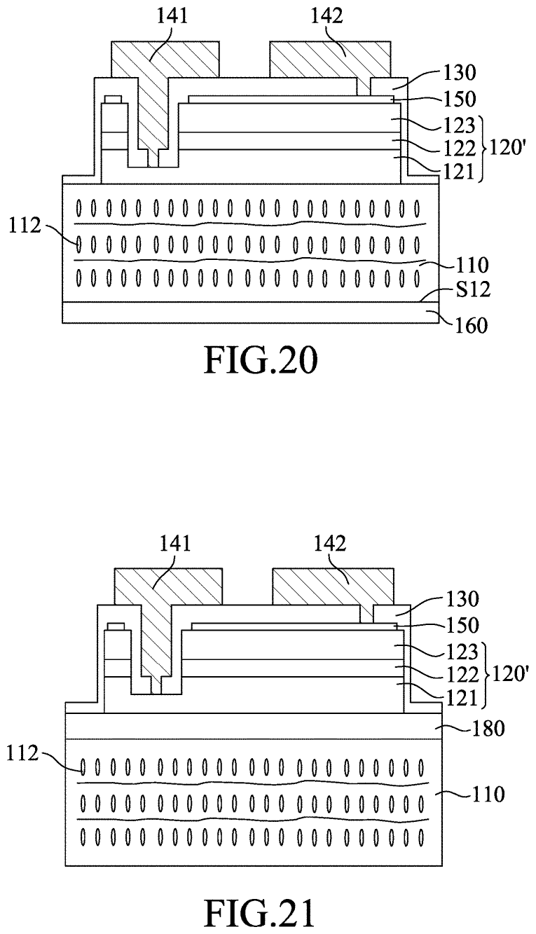

Referring to FIG. 20, a third embodiment of the light-emitting device according to the disclosure is generally similar to the first embodiment, except that, in the third embodiment, the light-emitting device further includes a second reflection layer 160 disposed on the lower surface S12 of the substrate 110. The second reflection layer 160 may be formed as a single layer structure or a multilayered structure, and may be used to increase a light-emitting angle of the light-emitting device. The light-emitting angle may not be smaller than 160°. In certain embodiments, the second reflection layer 160 may at least cover a middle portion of the lower surface S12 of the substrate 110. In alternative embodiments, the second reflection layer 160 may fully cover the lower surface S12 of the substrate 110. The second reflection layer 160 may be a reflection layer that is insulating, and may include at least one pair of two sublayers that are alternately stacked on one another and that have different refractive indices. For example, the two sublayers may include a silicon dioxide layer and a titanium dioxide layer.

In this embodiment, the light-emitting device can be applied in a backlight module of a display device. In such case, by having the second reflection layer 160, a light path of light emitted from the light-emitting device might be changed, which is conducive for increasing the light-emitting angle of the light-emitting device, reducing a thickness of the backlight module, and shrinking the size of the backlight module.

Referring to FIG. 21, a fourth embodiment of the light-emitting device according to the disclosure is generally similar to the first embodiment, except that, in the fourth embodiment, the light-emitting device further includes a transparent bonding layer 180 that interconnects the semiconductor light-emitting stack 120′ and the substrate 110.

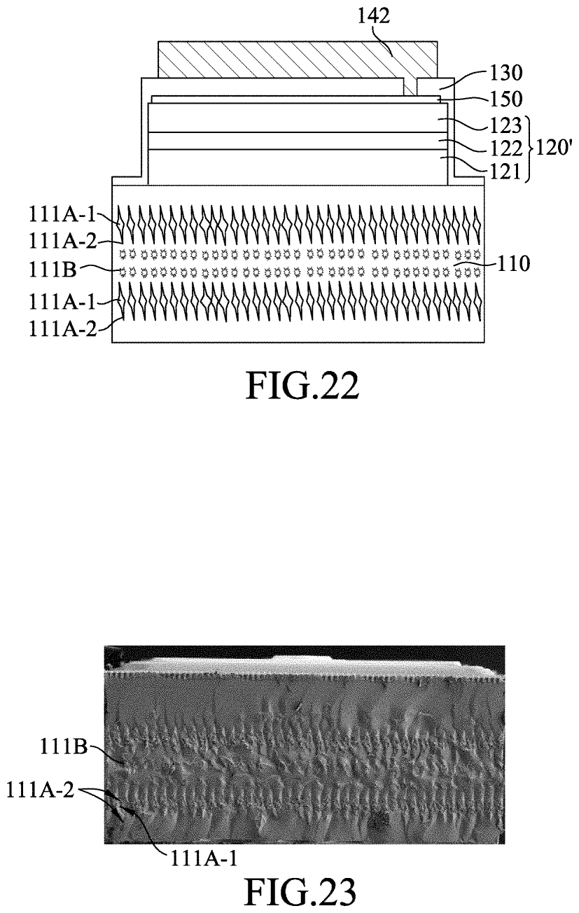

Referring to FIG. 22, a fifth embodiment of the light-emitting device according to the disclosure is generally similar to the first embodiment, except that, in the fifth embodiment, X (i.e., the number of the first laser inscribed marks 111) is not smaller than 3. Two adjacent ones of the first laser inscribed marks 111A, 111B may be connected with or separated from each other. Two adjacent ones of the first laser inscribed marks 111A, 111B are not intersecting with each other. Each of the topmost and lowest first laser inscribed marks 111A which are respectively located proximate to the upper surface S11 and the lower surface S12 of the substrate 110 is formed as a serrated structure, and includes a plurality of explosion points 111A-1 and cracks 111A-2 extending outward from the explosion points 111A-1. The at least one of the first laser inscribed marks 111B disposed between the topmost and lowest first laser inscribed marks 111A is formed with a plurality of explosion points.

FIG. 23 illustrates the first laser inscribed marks 111A, 111B are thin and distributed densely, and have an area percentage greater than 50% based on an area of the first side surface, which is conducive for splitting the light-emitting wafer, reducing the risk of each layer of the light-emitting device being damaged, and enhancing the luminous efficiency of the light-emitting device (i.e., increasing the amount of light emitted from the side of the substrate of the light-emitting device). In certain embodiments, the second laser inscribed marks 112 may have an area percentage greater than 50% based on an area of the second side surface.

In certain embodiments, the light-emitting device of this disclosure may be a deep ultraviolet light-emitting device, and the substrate 110 thereof may have a thickness ranging from 200 μm to 750 μm, so that the step for forming the second laser inscribed features 1120 in the substrate 110 may be performed using a multi-beam laser focusing at multiple focal points. For example, when the thickness of the substrate 110 ranges from 350 μm to 500 μm, the first laser inscribed features 1110 are formed in the substrate 110 along the first dicing line using a single-beam laser focusing at nine focal points, and the second laser inscribed features 1120 are formed in the substrate 110 along the second dicing line using a three-beam laser focusing at nine focal points. For another example, when the thickness of the substrate 110 is great than 500 μm, the first laser inscribed features 1110 are formed in the substrate 110 along the first dicing line using a three-beam laser focusing at nine focal points, and the second laser inscribed features 1120 are formed in the substrate 110 along the second dicing line using a five-beam laser focusing at nine focal points.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method for manufacturing a light-emitting device, comprising the steps of:
a) providing a light-emitting wafer which includes a substrate and a plurality of semiconductor light-emitting stacks spaced apart from one another by dicing lines, the dicing lines having a first dicing line that extends in a first direction, and a second dicing line that extends in a second direction perpendicular to the first direction, each of the semiconductor light-emitting stacks including a first conductivity type semiconductor layer, a light-emitting layer, and a second conductivity type semiconductor layer that are sequentially disposed on the substrate along a thickness direction that is perpendicular to the first direction and the second direction;
b) forming X number of first laser inscribed features in a cross sectional plane of the substrate along the first dicing line;
c) forming Y number of second laser inscribed features in a cross sectional plane of the substrate along the second dicing line, in which Y>X>0 and Y≥3; and
d) splitting the light-emitting wafer along the dicing lines to obtain a plurality of light-emitting devices.

2. The method of claim 1, wherein the substrate is made of sapphire, the first dicing line being located corresponding in position to an a-plane of the substrate, the second dicing line being located corresponding in position to an m-plane of the substrate.

3. The method of claim 1, wherein step b) is performed using a first laser beam, and step c) is performed using a second laser beam, a pulse energy of the first laser beam being greater than that of the second laser beam.

4. The method of claim 1, wherein each of steps b) and c) is performed using one beam laser focusing at multiple focal points.

5. The method of claim 1, wherein the substrate has a thickness ranging from 80 μm to 750 μm.

6. The method of claim 1, wherein each of the step (b) and step (c) is performed using a laser beam, and during step (b) and step (c), focal points of the laser beam in the substrate has a minimum distance from an upper surface of the substrate not smaller than 10 μm.

7. A light-emitting device, comprising:
a substrate including an upper surface, a first side surface, and a second side surface adjacent to said first side surface; and
a semiconductor light-emitting stack including
a first conductivity type semiconductor layer disposed over said upper surface of said substrate,
a light-emitting layer disposed on said first conductivity type semiconductor layer opposite to said substrate, and
a second conductivity type semiconductor layer disposed on said light-emitting layer opposite to said first conductivity type semiconductor layer,
wherein
said first side surface includes X number of first laser inscribed marks, and
said second side surface includes Y number of second laser inscribed marks, in which Y>X>0 and Y≥3.

8. The light-emitting device of claim 7, wherein an included angle between said upper surface and each of said first side surface and said second side surface ranges from 85° to 95°.

9. The light-emitting device of claim 7, wherein said first side surface includes a plurality of said first laser inscribed marks that are interconnected.

10. The light-emitting device of claim 7, wherein said second laser inscribed marks are regularly arranged.

11. The light-emitting device of claim 7, wherein said first laser inscribed mark is rougher than said second laser inscribed marks.

12. The light-emitting device of claim 7, wherein said first side surface includes a plurality of said first laser inscribed marks each extending in a first direction, at least one of said first laser inscribed marks including a plurality of first explosion points located at a central line of said first laser inscribed marks extending along the first direction, and first extending portions extending outwardly and irregularly from said first explosion points, respectively.

13. The light-emitting device of claim 7, wherein each of said second laser inscribed marks extends in a second direction, at least one of said second laser inscribed marks including a plurality of second explosion points located at a central line of said second laser inscribed marks extending along the second direction, and a plurality of second extending portions extending outwardly from said second explosion points, respectively, the second extending portions of one of said second laser inscribed marks and the second extending portions of an adjacent one of said second laser inscribed marks being connected with or separated from each other.

14. The light-emitting device of claim 7, wherein X is not smaller than 3, two adjacent ones of said first laser inscribed marks being connected with or separated from each other.

15. The light-emitting device of claim 7, wherein at least one of first laser inscribed marks is formed with a plurality of explosion points.

16. The light-emitting device of claim 7, wherein said second laser inscribed marks are arranged in parallel, a distance between two adjacent ones of said second laser inscribed marks being greater than 0 μm and being not greater than 30 μm.

17. The light-emitting device of claim 7, wherein said second laser inscribed marks have an area percentage greater than 50% based on an area of said second side surface.

18. The light-emitting device of claim 7, wherein a minimum distance between a central line of each of the first laser inscribed mark(s) and said upper surface is not smaller than 15 μm, and a minimum distance between a central line of the topmost one of said second laser inscribed marks and said upper surface is not smaller than 10 μm.

19. The light-emitting device of claim 13, wherein said second side surface further includes a transverse crack parallel to said upper surface of said substrate.

20. The light-emitting device of claim 19, wherein said second extending portions of each of said second laser inscribed marks extend along a thickness direction of said substrate and terminate at said transverse crack.

21. The light-emitting device of claim 7, wherein said upper surface of said substrate has a rectangular shape, and has a first side connected to said first side surface and a second side connected to said second side surface, a length of said first side being shorter than that of said second side.

22. The light-emitting device of claim 7, wherein said first laser inscribed mark includes a plurality of first explosion points and each of said second laser inscribed marks includes a plurality of second explosion points, a distance between two adjacent ones of said first explosion points being smaller than that between two adjacent ones of said second explosion points.

23. The light-emitting device of claim 22, wherein the distance between two adjacent ones of said first explosion points ranges from 1 μm to 12 μm, and the distance between two adjacent ones of said second explosion points ranges from 5 μm to 20 μm.
